(19) United States
(12) Patent Application Publication
(10) Pub. No.: US 2016/0237570 A1
(43) Pub. Date: Aug. 18, 2016

(54) GAS DELIVERY APPARATUS FOR PROCESS EQUIPMENT

(71) Applicant: Applied Materials, Inc., Santa Clara, CA (US)

(72) Inventors: Tien Fak Tan, Campbell, CA (US); Phong Pham, San Jose, CA (US); Dmitry Lubomirsky, Cupertino, CA (US)

(73) Assignee: Applied Materials, Inc., Santa Clara, CA (US)

(21) Appl. No.: 14/622,218

(22) Filed: Feb. 13, 2015

(51) Int. Cl. C23C 18/16; F16L 58/08; F16L 9/02; C23C 16/50; C23C 16/455

(52) U.S. Cl. CPC C23C 18/1637; C23C 16/50; C23C 16/455; F16L 9/02; F16L 58/08

(57) ABSTRACT

A method of preparing an aluminum tube for use as a gas line includes plating a nickel alloy throughout internal surfaces of the aluminum tube, to form the gas line. A gas line for transport of gases includes an aluminum tube with a nickel alloy coating throughout internal surfaces of the tube. A plasma processing apparatus includes at least two process chambers for exposing a workpiece to a plasma, and a gas line that supplies, from one or more inlet ports, one or more gases for generating the plasma to two outlet ports. Each of the two outlet ports interfaces to a respective one of the process chambers, and the gas line includes an aluminum tube with a nickel alloy coated internal surface.

### TECHNICAL FIELD

The present disclosure is in the field of plasma processing equipment. More specifically, embodiments that reduce contamination from plasma generators that operate at relatively high pressures are disclosed.

### BACKGROUND

In plasma processing, plasmas create ionized and/or energetically excited species for interaction with workpieces that may be, for example, semiconductor wafers. To create and/or maintain a plasma, one or more gases are introduced into a space within a plasma generator, and one or more radio frequency (RF) and/or microwave generators generate electric and/or magnetic fields to ignite a plasma from the gases to create the ionized and/or energetically excited species. The ionized and/or energetically excited species, along with unreacted gases from which they are generated, are collectively referred to herein as “plasma products.” In some wafer processing systems, a plasma is generated in the same location as one or more wafers being processed; in other cases, a plasma is generated in one location and moves to another location where the wafer(s) are processed. Plasma products often include highly energetic and/or corrosive species and/or highly energetic electrons, such that the equipment that produces them sometimes degrades from contact with the energetic species and/or electrons. Plasmas can be generated at a variety of pressures, with typical pressures for generation and/or use of plasma products ranging from milliTorr to thousands of Torr. The effects of plasma products on the items being processed, and the processing equipment, can vary according to the pressure utilized.

### SUMMARY

In an embodiment, a method of preparing an aluminum tube for use as a gas line includes plating a nickel alloy throughout internal surfaces of the aluminum tube, to form the gas line.

In an embodiment, a gas line for transport of gases includes an aluminum tube with a nickel alloy coating throughout internal surfaces of the tube.

In an embodiment, a plasma processing apparatus includes two process chambers for exposing a workpiece to a plasma, and a gas line that supplies, from one or more inlet ports, one or more gases for generating the plasma to two outlet ports. Each of the two outlet ports interfaces to a respective one of the process chambers, and the gas line includes an aluminum tube with a nickel alloy coated internal surface.

### BRIEF DESCRIPTION OF THE DRAWINGS

The present disclosure may be understood by reference to the following detailed description taken in conjunction with the drawings briefly described below, wherein like reference numerals are used throughout the several drawings to refer to similar components. It is noted that, for purposes of illustrative clarity, certain elements in the drawings may not be drawn to scale. In instances where multiple instances of an item are shown, only some of the instances may be labeled, for clarity of illustration.

FIG. 1 schematically illustrates major elements of a plasma processing system, according to an embodiment.

FIG. 2A schematically illustrates major elements of a plasma processing system, in a cross-sectional view, according to an embodiment.

FIG. 2B shows a perspective view of an exemplary gas line 215 that connects one inlet gas source to two plasma sources, according to an embodiment.

FIGS. 3A and 3B show scanning electron microscope (SEM) photos and elemental analyses of representative particles from SST lines.

FIG. 4 is a flowchart of a process for manufacturing and testing a Ni alloy plated Al gas line, according to an embodiment.

FIG. 5A schematically shows, in plan view, an exemplary wet chemical apparatus for cleaning and plating internal surfaces of gas lines, according to an embodiment.

FIG. 5B shows a schematic cross section of apparatus of FIG. 5A.

### DETAILED DESCRIPTION

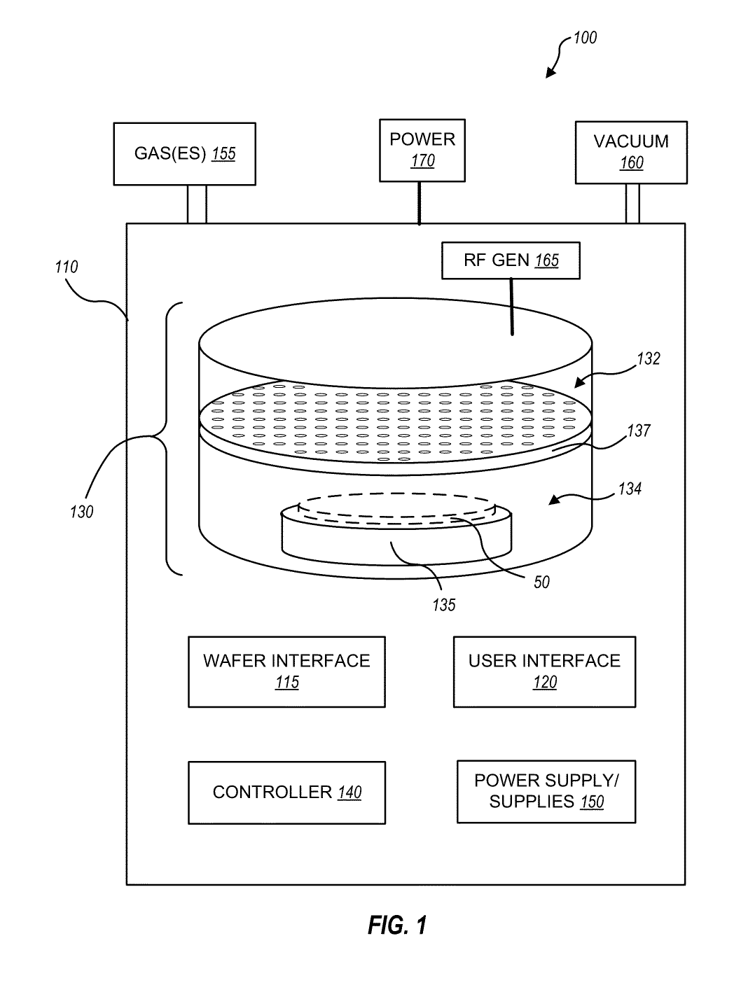

FIG. 1 schematically illustrates major elements of a plasma processing system 100, according to an embodiment. System 100 is depicted as a single wafer, semiconductor wafer plasma processing system, but it will be apparent to one skilled in the art that the techniques and principles herein are applicable to processing systems for any type of workpiece (e.g., items that are not necessarily wafers or semiconductors). Processing system 100 includes a housing 110 for a wafer interface 115, a user interface 120, a plasma processing unit 130, a controller 140 and one or more power supplies 150. Processing system 100 is supported by various utilities that may include gas(es) 155, external power 170, vacuum 160 and optionally others. Internal plumbing and electrical connections within processing system 100 are not shown, for clarity of illustration.

Processing system 100 is shown as a so-called indirect plasma processing system that generates a plasma in a first location and directs the plasma and/or plasma products (e.g., ions, molecular fragments, energized species and the like) to a second location where processing occurs. Thus, in FIG. 1, plasma processing unit 130 includes a plasma source 132 that supplies plasma and/or plasma products for a process chamber 134. Process chamber 134 includes one or more wafer pedestals 135, upon which wafer interface 115 places a workpiece 50 (e.g., a semiconductor wafer, but could be a different type of workpiece) for processing. In operation, gas(es) 155 are introduced into plasma source 132 and a radio frequency generator (RF Gen) 165 supplies power to ignite a plasma within plasma source 132. Plasma and/or plasma products pass from plasma source 132 through a diffuser plate 137 to process chamber 134, where workpiece 50 is processed.

An indirect plasma processing system for semiconductor wafer processing is illustrated in FIG. 1 and elsewhere in this disclosure. However, it should be clear to one skilled in the art that the techniques, apparatus and methods disclosed herein are equally applicable to direct plasma processing systems (e.g., where a plasma is ignited at the location of the workpiece(s)) and/or to systems that process workpieces other than semiconductor wafers.

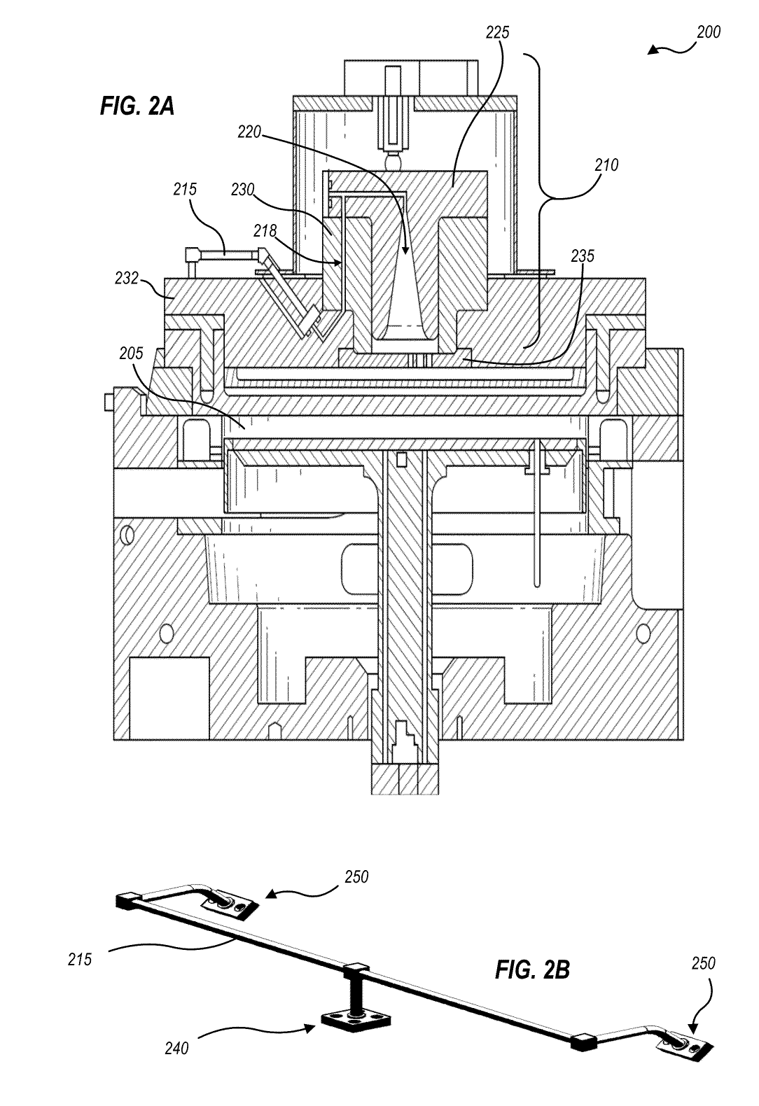

FIG. 2A schematically illustrates major elements of a plasma processing system 200, in a cross-sectional view, according to an embodiment. Plasma processing system 200 is an example of plasma processing unit 130, FIG. 1. Plasma processing system 200 includes a process chamber 205 and a plasma source 210. Plasma source 210 introduces one or more source gases (e.g., gases 155, FIG. 1) through an inlet gas line 215 and an internal passage 218 that passes through a chamber lid 232, an insulator 230 and an RF electrode 225. As shown in FIG. 2A, internal passage 218 connects with a nozzle 220 formed in RF electrode 225. Insulator 230 electrically insulates RF electrode 225 from chamber lid 232, which may be held at electrical ground (or the polarity of ground vs. powered electrode may be reversed). Inlet gas line 215 slopes downwardly as it approaches plasma source 210, to reduce the possibility of electrical arcing between inlet gas line 215 and RF electrode 225 by keeping gas line 215 and RF electrode 225 as far as possible from one another. Plasma and/or plasma products pass through apertures 237 formed in a diffuser 235, toward process chamber 205.

Plasma processing system 200 is shown as a single plasma generator and processing chamber in the cross-sectional plane of FIG. 2A, but certain features shown, particularly inlet gas line 215, may be shared with other instances of plasma generators and processing chambers in other cross-sectional planes.

FIG. 2B shows a perspective view of an exemplary gas line 215 that connects one or more source gases from a shared gas inlet to two plasma sources (e.g., plasma sources 210, FIG. 2A). Accordingly, gas line 215 includes one inlet fixture 240 and two outlet fixtures 250, as shown.

In an embodiment, plasma processing system 200 generates plasma products that are suitable for etching dielectric materials used in semiconductor fabrication. Typical source gases that would be introduced into plasma processing system 200 through inlet gas line 215 include, for example, SF₆, NF₃, NH₃, H₂, He and Ar. Typical plasmas formed in plasma processing system 200 operate within a range of 1 to 30 Torr, and especially within a range of 10 to 12 Torr.

Inlet gas line 215 is advantageously formed of aluminum that is coated with a suitable (e.g., durable and pinhole-free) nickel alloy layer inside and/or outside, in embodiments. It is understood that when nickel (Ni) is referred to herein, either nickel or any nickel containing alloy is meant. Although stainless steel (“SST”) is typically utilized for gas lines of at least some process gases in plasma processing equipment, and is sometimes nickel plated for chemical resistance, SST remains vulnerable to attack by free fluorine. It is believed that Ni alloy plating does not adhere well to SST, and may form pinholes, voids and/or other forms of incomplete coverage that allow local attack of the SST by the free fluorine. Free fluorine may be generated in locations such as nozzle 220 and an adjacent region just above diffuser 235, and can back diffuse through internal passage 218 to gas line 215. Back diffusion of fluorine to gas line 215 may especially occur in plasma equipment that operates at a relatively high operating pressure (e.g., greater than about 5 Torr, and especially 10 to 12 Torr in plasma source 210). Back diffusion may also occur or increase if gas line 215 serves multiple process chambers. That is, when certain events occur within plasma source 210 and/or downstream components such as chamber 205, momentary surges of gases and/or plasma products may occur as pressure within gas line 215 balances with respect to a second (and/or third, etc.) plasma generator connected to gas line 215. Events that may cause such surges include but are not limited to plasma ignition, starting or stopping of gas flows, opening and closing of vacuum gates or doors between chambers, and the like.

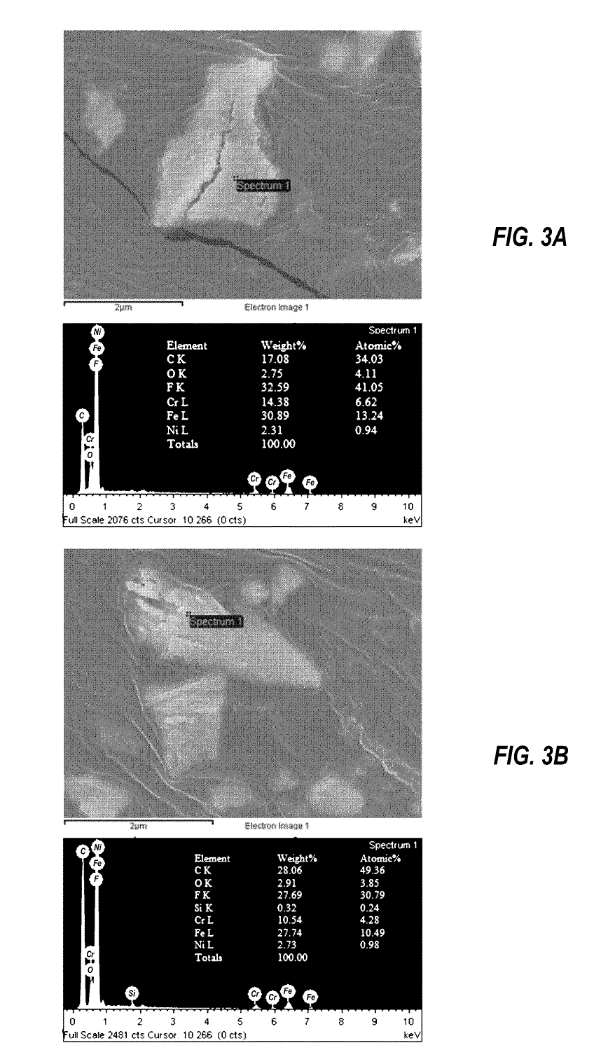

When SST is used for gas line 215, attack of the SST by free fluorine can lead to gas line 215 shedding particles that may contain, among other elements, Fe and Cr. Such particles are undesirable in semiconductor processing because they can generate defects (e.g., they can short circuit adjacent conductors, or alter patterns printed on various semiconductor layers) and from an atomic contamination standpoint (e.g., Fe and Cr can incorporate into semiconductor materials and affect electronic properties of the materials). FIGS. 3A and 3B show scanning electron microscope (SEM) photos and elemental analyses of representative particles from SST lines. Of interest are the breakdowns of elements by weight % and atomic % available in the elemental analyses. These particular analyses indicate significant amounts of Cr and Fe in the analyzed particles.

When gas line 215 is formed of suitably processed Ni alloy coated Al instead, particle generation is suppressed. Aluminum is advantageous in that its satisfactory use in plasma wafer processing systems is well established. For example, any of RF electrode 225, chamber lid 232, and/or diffuser 235, FIG. 2A, may also be formed of Al. In embodiments, the base Al is of the well known “6061” alloy type, having the following elemental composition:

| Element | Minimum percentage | Maximum percentage |
|---|---|---|
| Al | 95.85 | 98.56 |
| Si | 0.4 | 0.8 |
| Fe | 0 | 0.7 |
| Cu | 0.15 | 0.40 |
| Mn | 0 | 0.15 |
| Mg | 0.8 | 1.2 |
| Cr | 0.04 | 0.35 |
| Zn | 0 | 0.25 |
| Ti | 0 | 0.15 |
| Others | 0 | 0.05 each, 0.15 total |

Advantageously, to increase corrosion resistance of Al, the Ni alloy plating forms a thickness in the range of 0.0008 to 0.0015 inches, especially the range of 0.0010 to 0.0012 inches. Ni alloy plating also advantageously includes a phosphorous content in the range of 8% to 15%, especially the range of 10% to 12%, according to the test methods described in ASTM Practice E 60 or Test Methods E 352.

Embodiments that make and use gas line 215 formed of Ni alloy plated Al are now disclosed.

Using electroplating to generate a suitable Ni alloy coating on the interior of an Al tube or gas line can be problematic because ions in an electroplating solution are guided by electric fields therein, and such fields will not extend to internal surfaces deep within a tube. Embodiments herein utilize electroless Ni alloy plating and a heat treatment to generate a Ni alloy coated tube that has been found in tests to be suitable for use in equipment that may expose the tube to free fluorine. The methods now described are advantageously capable of producing gas lines that are internally Ni alloy coated or plated throughout; that is, all of the internal surfaces of such gas lines are Ni plated, not just parts of the surfaces. Coating internal surfaces throughout a gas line provides the significant advantage that no parts of the internal surfaces are unprotected from the highly corrosive environment that they may be subjected to.

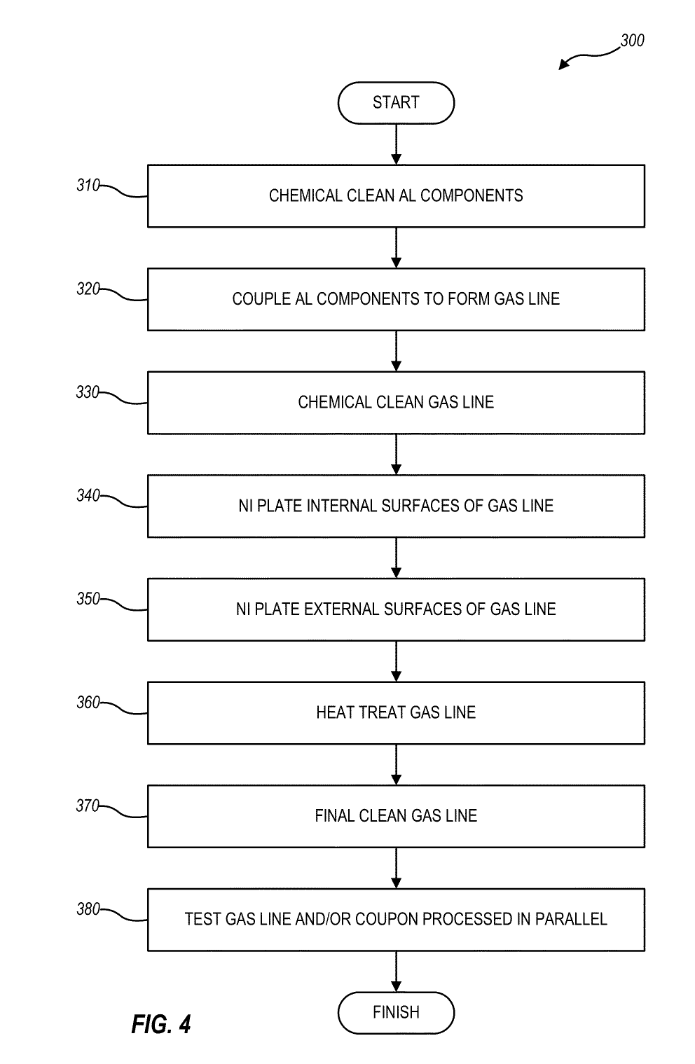

FIG. 4 is a flowchart of a process 300 for manufacturing and testing a Ni alloy plated Al gas line, such as gas line 215, FIG. 2A. It will be evident to those skilled in the art that individual subprocesses or all subprocesses of process 300 may be performed on individual Al components and/or fabricated gas lines, or multiples of such components and/or gas lines in batch processes. Subprocesses of process 300 need not be performed by a single entity or at a single location; components and/or fabricated gas lines may be sent from one location to another, or to different business entities, to perform various ones of the subprocesses. It will also be evident to those skilled in the art that certain subprocesses may be omitted, or their order rearranged, within process 300.

As process 300 begins, Al components that will be joined to form the gas line are chemically cleaned, 310, which may be considered optional if the Al components are believed to be clean enough as-fabricated, and in view of subsequent cleaning. Cleaning may include use of surfactants and/or chemicals and may optionally be followed by rinsing and/or drying. The Al components are coupled, 320, to form the gas line. Coupling is typically done by welding, but other forms of coupling are possible; it may be advantageous to utilize coupling methods that result in inner surfaces that are clean and free of residue with minimal crevices, steps or discontinuities. Also, advantageously, all machining and coupling operations are performed before Ni plating, so that all machining induced scratches and the like are covered by the Ni plating. The gas line is chemically cleaned, 330, again optionally followed by rinsing and/or drying. Chemical cleaning of the gas line may include, for example, cleaning exterior and/or interior surfaces of the gas line with dilute HF and/or HNO₃, again optionally followed by rinsing and/or drying.

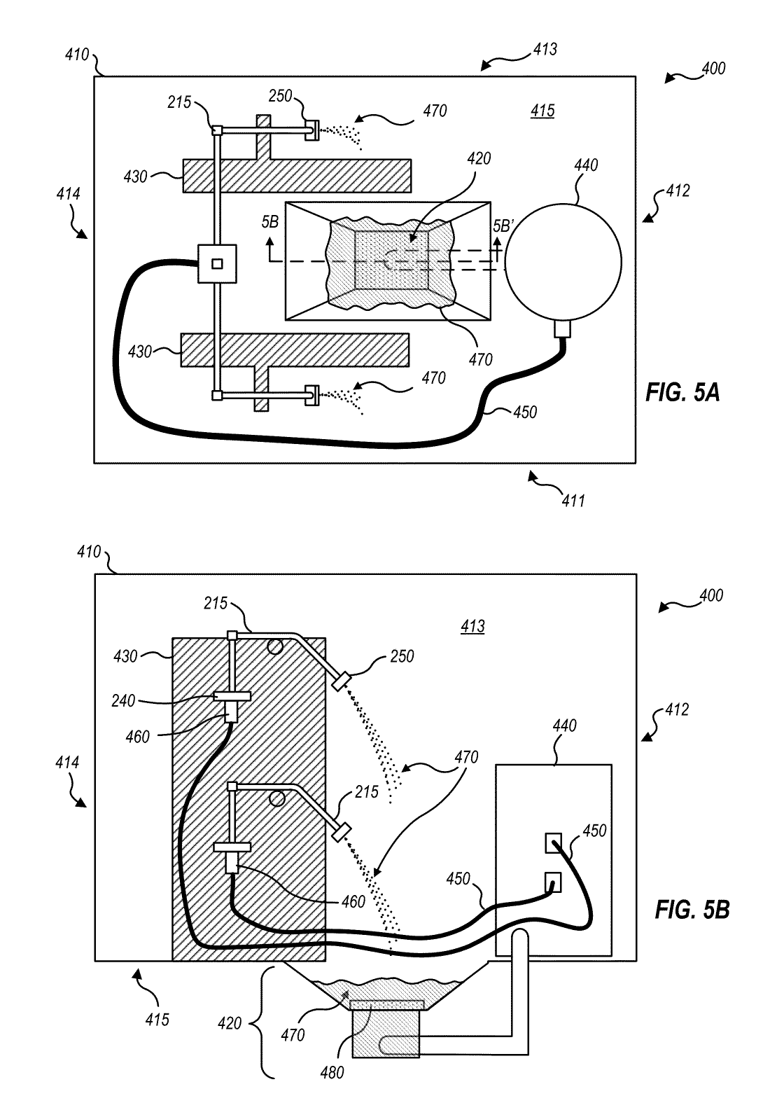

Internal surfaces of the gas line are plated with electroless Ni alloy, 340. In preparation for the internal surface Ni alloy plating, external surfaces that may have a critical flatness or other dimensional requirement may be masked, to avoid incidental electroless Ni buildup on such surfaces. Advantageously, to promote uniform Ni alloy plating on the internal surfaces of the gas line(s), electroless Ni alloy plating solution is pumped through the fabricated gas line. Cleaning 330 and plating 340 may be done on individual fabricated gas lines, or fixtures may be utilized to circulate cleaning or Ni alloy plating solutions through several fabricated gas lines at once, in serial or parallel arrangements (see, e.g., FIGS. 5A, 5B). Electroless Ni plating may use nickel sulfate, NiSO₄ (or its hydrated form, NiSO₄(H₂O₆)) as a Ni source, and sodium hypophosphite, NaPO₂H₂ as a reducing agent. Other possible Ni sources include nickel chloride, NiCl₂, and nickel acetate, Ni(CH₃CO₂)₂ or their hydrated forms. Other possible reducing agents are sodium borohydride, NaBH₄, hydrazine, N₂H₄, and dimethylamine borane, (CH₃)₂)NH.BH₃.

External surfaces of the gas line are plated with Ni alloy, 350. In embodiments, the external surface Ni plating 350 also performs electroless Ni plating, like 340, but in other embodiments Ni plating 350 is electrolytic Ni plating, since outer surfaces of the gas line would be accessible to ions guided by electric fields in an electrolytic plating bath. Plating 340 and 350 may be performed in either order, optionally with rinses and/or drying in between or following the last of the plating. During the outer surface Ni alloy plating 350, ends of the gas line are optionally plugged.

Optionally but advantageously, the gas line is heat treated, 360, to promote grain growth of the electroless Ni alloy plating, to harden the Ni plating and improve its adhesion to Al. For example, in embodiments the gas line is heat treated at 120 C to 130 C for at least one hour; in other embodiments the gas line is heat treated at 140 C to 150 C for at least one hour. The gas line goes through a final clean, 370, to remove chemicals and contamination from plating 340, 350. Optionally, the gas line (and/or a coupon processed in parallel with the gas line) is tested, 380. Testing may include for example running an acidic solution through the gas line and/or swabbing inner or outer surfaces of the gas line to obtain a sample of material that remains on the surface(s) and/or is loosened or chemically removed by the acidic solution. Testing may also include visual inspection, plating thickness testing of cross-sectioned coupons as per ASTM B 487, plating thickness testing of gas lines and/or coupons before and after plating using a micrometer, plating thickness testing using Beta backscatter analysis as per ASTM B 567, plating thickness testing using X-ray spectrometry as per ASTM B 568, surface finish testing as per ANSI/ASME B46.1, adhesion testing as per ASTM B 571, porosity testing as per section C2 of Annex C of ISO 4527, phosphorous content testing as per ASTM Practice E 60 or Test Method E 352, corrosion resistance testing as per ASTM G 31, long term HCl exposure testing, microhardness testing as per ASTM B 578, outgassing testing as per ASTM E 1559, ionic contamination testing as per US EPA methods 300.0, 300.7, black light inspection and/or metallography inspection as per ASTM E 3.

Process 300 can, in embodiments, be performed on multiple gas lines in parallel to improve manufacturing volumes and consistency of the gas lines so produced. For example, fixtures may be built to flow a chemical or chemical mixture through one or more gas lines, in serial or parallel combinations. Certain gas lines that include branches (e.g., that form T-shaped or Y-shaped, or more complex topographies) may be connected to a chemical source in one branch, such that a chemical stream that is introduced splits internally and drains from the gas line through two or more branches. The chemical or chemical mixture may be an electroless nickel alloy plating solution, a cleaning solution, a rinsing solution, and/or combinations or sequences of such solutions. The chemical or chemical mixture may flow through the gas lines from a source reservoir to a waste reservoir, or may be recycled by being pumped from a single reservoir through the gas lines back to the single reservoir. In embodiments, the chemical or chemical mixture is strained and/or filtered to promote adhesion, cleanliness and uniformity of the plating. Also, Al coupons can be processed at the same time as gas lines, and can be analyzed for thickness of the electroless Ni plating, concentrations of Ni, P and contaminants, hardness of the plating, and the like. The fixtures used for plating of gas lines can have features attached for coupon processing.

FIG. 5A schematically shows, in plan view, an exemplary wet chemical apparatus 400 for cleaning and plating internal surfaces of gas lines 215. FIG. 5B shows a schematic cross section of apparatus 400. For clarity of illustration, FIG. 5B shows certain features of apparatus 400 as if cross-sectioned at line 5B-5B′ in FIG. 5A, while the remaining features are shown as would be seen in an elevational view with wall 411 of tank 410 removed. It will be appreciated by one skilled in the art upon reading and understanding the disclosure below, that the features of apparatus 400 are exemplary only and may be modified in many ways for cleaning and plating internal surfaces of differing numbers and/or types of devices that include or are formed of tubes, such as gas line 215.

Apparatus 400 is configured to pump one or more chemicals, chemical mixtures and/or rinsing solutions (any of which may be called “a chemical” herein) through gas lines 215 to provide electroless Ni alloy plating, other chemical activity, and/or rinsing, on internal surfaces of the gas lines. As shown, apparatus 400 includes a generally cuboid tank 410 including side walls 411, 412, 413 and 414 and a bottom surface 415; in other embodiments, tank 410 may assume different shapes. Bottom surface 415 includes a sump portion 420 in which a chemical 470 may pool for access by a pump 440. Racks 430 are configured to hold gas lines 215. FIG. 5B shows two gas lines 215 being held by racks 430, but tank 410 and racks 430 may configured to accommodate any number and configuration of gas lines for processing. Pump 440 pumps chemical 470 into feed tubes 450. Feed tubes 450 terminate in fittings 460 that are configured to fit inlet fixtures 240 of gas lines 215. Chemical 470 thus flows into gas lines 215, contacting internal surfaces thereof until it exits at outlet fixtures 250, whereupon chemical 470 drips back into tank 410 for recycling through pump 440.

Apparatus 400 can thus be utilized to implement several subprocesses of process 300, FIG. 4. For example, a cleaning solution can be utilized as chemical 470 to clean internal surfaces of gas lines 215, optionally followed by use of water as chemical 470 to rinse the cleaning solution out of gas lines 215. The same apparatus 400 can then be utilized to pump electroless Ni alloy plating solution as chemical 470 to Ni plate gas lines 215, which again can optionally be followed by a water rinse. Alternatively, multiple instances of apparatus 400 can be utilized for different subprocesses, to avoid cross-contamination.

Many optional features and variations will be apparent to those skilled in the art. For example, FIGS. 5A and 5B show sump portion 420 with an optional strainer 480 which may be omitted in embodiments, or replaced with one or more filters, either upstream or downstream of pump 440. Other optional features include:
provisions for temperature control of chemical 470 and/or gas lines 215;
features for adding, mixing, and/or removing chemical 470 to or from tank 410;
manifolds or valves to distribute chemical 470 among gas lines 215, including valves that allow flow of chemical 470 to individual gas lines 215 to be halted for addition or removal of ones of gas lines 215, while others of gas lines 215 continue to flow chemical 470;
drain tubes fitted to outlet fixtures 250 of gas lines 215 to carry chemical 470 therefrom to a waste tank or to a reservoir used in place of sump portion 420; and/or
drying gases (e.g., clean dry air or N2) can be provided through feed tubes 450 and/or fittings 460, or separate tubes and/or fittings can be provided with the drying gases, to dry internal surfaces of gas lines 215.

Gas lines with internal nickel alloy plating can be tested to assure that the nickel alloy plating is functioning as designed. For example, gas line 215 can be tested by using a swab to rub one or more internal surfaces with a mildly acidic solution, and performing elemental analysis on particles found on the swab (e.g., with inductively coupled plasma mass spectroscopy, or ICP-MS). Because the swabbing method is technique sensitive, a total number of particles obtained is not a reliable indicator of suitability. However, elemental analysis can be performed on the particles that are found. This analysis can serve as a monitor for efficacy of the gas line base material, nickel alloy plating and/or other process variables in suppressing elements that will be harmful in workpiece processing. Particles obtained by swabbing will generally contain Ni, but other elements found on the particles can provide information relevant to suitability. For example, when SST gas lines are analyzed in this manner, high ratios of Fe and/or Cr to Ni are found, whereas when Al gas lines are analyzed in the same way, much lower ratios of Fe and/or Cr to Ni are found. Also, a ratio of Ni to P can be determined in order to monitor P concentration of the electroless Ni plating. The same technique can be utilized to evaluate variables such as gas line surface finish, thickness of nickel alloy plating, cleaning techniques, heat treatment variables and the like. This technique has repeatedly validated that aluminum gas lines with electroless nickel plating as described herein reduce Fe and Cr, in particles obtained on swabs, to nearly undetectable levels (e.g., reduction of Fe and Cr by factors of at least 10, often by factors of 100 or greater).

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” or “a recipe” includes a plurality of such processes and recipes, reference to “the electrode” includes reference to one or more electrodes and equivalents thereof known to those skilled in the art, and so forth. Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

We claim:

1. A method of preparing an aluminum tube for use as a gas line, the method comprising:
plating a nickel alloy throughout internal surfaces of the aluminum tube, to form the gas line.

2. The method of claim 1, wherein plating the nickel alloy comprises plating the nickel alloy to a thickness in the range of 0.0010 to 0.0012 inches.

3. The method of claim 1, wherein plating the nickel alloy comprises flowing an electroless nickel plating solution through the aluminum tube, the electroless nickel plating solution providing the nickel alloy with a phosphorous concentration in the range of 10 to 12 percent.

4. The method of claim 1, further comprising plating a nickel alloy on external surfaces of the aluminum tube.

5. The method of claim 4, wherein plating the nickel alloy on the external surfaces of the aluminum tube comprises plating the nickel alloy using an electroless nickel plating solution.

6. The method of claim 4, wherein plating the nickel alloy on the external surfaces of the aluminum tube comprises plating the nickel alloy using electrolytic nickel plating.

7. The method of claim 1, further comprising coupling aluminum components to form the aluminum tube.

8. The method of claim 1, further comprising cleaning the internal surfaces before plating the nickel alloy.

9. The method of claim 1, further comprising heat treating the gas line after plating the nickel alloy, sufficient to enlarge a grain structure of the nickel alloy.

10. The method of claim 9, wherein heat treating comprises heat treating the gas line at a temperature of at least 120 C for at least one hour.

11. A gas line for transport of gases, comprising an aluminum tube with a nickel alloy coating throughout internal surfaces of the tube.

12. The gas line of claim 11, wherein the nickel alloy coating forms a thickness in the range of 0.0010 to 0.0012 inches.

13. The gas line of claim 11, wherein the nickel alloy coating comprises 10 to 12 percent phosphorous.

14. The gas line of claim 11, further comprising a nickel coating on exterior surfaces of the tube.

15. The gas line of claim 9, the aluminum tube comprising an aluminum type 6061 alloy.

16. A plasma processing apparatus, comprising:
at least two process chambers for exposing a workpiece to a plasma;
a gas line that supplies, from one or more inlet ports, one or more gases for generating the plasma to at least two outlet ports, wherein each of the at least two outlet ports interfaces with a respective one of the process chambers;
wherein the gas line includes an aluminum tube with a nickel alloy coated internal surface.

17. The plasma processing apparatus of claim 16, wherein:
at least one of the process chambers generates the plasma at a pressure of at least 10 Torr, and
the plasma comprises free fluorine.

18. The plasma processing apparatus of claim 16, wherein the nickel alloy comprises 10 to 12 percent phosphorous.

19. The plasma processing apparatus of claim 16, wherein the nickel alloy forms a thickness in the range of 0.0010 to 0.0012 inches.
